(19) United States
(12) Patent Application Publication
(10) Pub. No.: US 2021/0288523 A1
(43) Pub. Date: Sep. 16, 2021

(54) WIRELESS CHARGER

(71) Applicant: LUXSHARE PRECISION INDUSTRY CO., LTD., Shenzhen (CN)

(72) Inventors: Linbiao HU, Dongguan City (CN); Hua YI, Dongguan City (CN); Zuohua HUANG, Dongguan City (CN); Xianfeng LI, Dongguan City (CN)

(73) Assignee: LUXSHARE PRECISION INDUSTRY CO., LTD., Shenzhen (CN)

(21) Appl. No.: 15/931,978

(22) Filed: May 14, 2020

(30) Foreign Application Priority Data
Mar. 13, 2020 (CN) 202020309920.2

(51) Int. Cl. H02J 50/10; H02J 7/02; H02J 7/00; H02J 50/40; H02J 50/90; H01F 41/04

(52) U.S. Cl. CPC H02J 50/10; H02J 7/02; H01F 41/041; H02J 50/40; H02J 50/90; H02J 7/0042

(57) ABSTRACT

The present disclosure discloses a wireless charger. The wireless charger includes a housing, a printed circuit board (PCB), an induction coil, a connector and a connection component; the housing includes a housing body and a bottom cover, an installation cavity is disposed inside the housing body, the housing body is provided with an installation groove communicating with the installation cavity, a bottom side of the installation cavity is provided with an opening, and the bottom cover is disposed on the opening and closes the opening; the PCB and the induction coil are disposed in the installation cavity; the induction coil is connected to the PCB, and the induction coil and the bottom cover are located on opposite sides of the PCB, respectively; the connector is disposed in the installation groove and connected to the PCB; and the connection component connects the bottom cover and the PCB.

### CROSS-REFERENCE TO RELATED APPLICATION(S)

This application claims priority to a Chinese patent application No. 202020309920.2 filed on Mar. 13, 2020, disclosure of which is incorporated herein by reference in its entirety.

### TECHNICAL FIELD

The present disclosure relates to the technical field of chargers, in particular to a wireless charger.

### BACKGROUND

With the rapid development of digital electronic technologies, smart wearable products are very popular among people. Taking smart watches as an example, smart watches are a widely used type of smart wearable products, and can not only play music, display time and intelligently perform positioning, but also measure blood pressure and heart rate.

In the related art, the smart watch is usually charged by a wireless charger of the watch. For example, in the previous application with the application number CN201920751658.4, a wireless charger of a watch is disclosed, does not require a charging wire and has the characteristics of easy portability and fast charging compared with a wired charger. However, a Printed Circuit Board (PCB) of the wireless charger of the watch is clamped with a bottom cover by a face casing and the PCB is fixed to the face casing by bolts, the PCB supports an induction coil by an Ethylene/vinyl acetate (EVA) cotton, and the induction coil is located between the PCB and the face casing. When the induction coil needs to be maintained, the bottom cover and the PCB need to be disassembled in sequence, the maintenance efficiency is low, and additional EVA cotton is required, resulting in increased costs.

### SUMMARY

The present disclosure provides a wireless charger to solve the problem of low maintenance efficiency when the bottom cover and PCB of the wireless charger of the watch in the related art needs to be disassembled in sequence at the moment of maintaining the induction coil.

The present disclosure provides a wireless charger. The wireless charger includes a housing, a printed circuit board (PCB), an induction coil, a connector and a connection component; the housing includes a housing body and a bottom cover, an installation cavity is disposed inside the housing body, the housing body is provided with an installation groove communicating with the installation cavity, a bottom side of the installation cavity is provided with an opening, and the bottom cover is disposed on the opening and closes the opening; the PCB is disposed in the installation cavity; the induction coil is disposed in the installation cavity and connected to the PCB, where the induction coil and the bottom cover are located on opposite sides of the PCB, respectively; the connector is disposed in the installation groove and connected to the PCB; and the connection component connects the bottom cover and the PCB.

Alternatively, the connection component includes a bolt and a nut, the bolt passes through the bottom cover and the PCB in sequence and is in threaded connection with the nut, and the induction coil is abutted to the nut.

Alternatively, the wireless charger includes a plurality of connection components; and the wireless charger further includes a hanging buckle, where an installation hole is disposed on a side wall of the housing body, the hanging buckle passes through the installation hole, and one bolt passes through the bottom cover, the PCB, and the hanging buckle in sequence to be in threaded connection with a corresponding nut.

Alternatively, the bottom cover has a first end surface and a second end surface disposed oppositely, the first end surface is located in the installation cavity, the second end surface is located outside the installation cavity, and a countersunk hole is disposed on the second end surface; and

the bolt passes through the countersunk hole and a head of the bolt does not exceed the second end surface.

Alternatively, the wireless charger further includes a protective film covering the second end surface and shielding the countersunk hole.

Alternatively, two positioning ribs are spaced apart on a side wall of the installation cavity, a positioning groove is formed between the two positioning ribs, a positioning protrusion is provided on the PCB, and the positioning protrusion is inserted into the positioning groove.

Alternatively, the housing body includes a middle frame and a top cover, the middle frame and the top cover surround and form the installation cavity, the induction coil abuts the top cover, and the installation groove and the opening are both disposed in the middle frame.

Alternatively, the connector is a universal serial bus (USB), two lugs are spaced apart on the USB, two connection grooves are spaced apart on the PCB, and the two lugs are inserted into the two connection grooves, respectively.

Alternatively, a first clamping protrusion is disposed on the bottom cover, and the first clamping protrusion abuts the PCB in a plugging direction of the USB.

Alternatively, a second clamping protrusion is disposed on the middle frame, and the second clamping protrusion abuts the bottom cover in the plugging direction of the USB.

The present disclosure provides a wireless charger including a housing, a PCB, an induction coil, a connector and a connection component. The PCB is fixed to the bottom cover through the connection component, and the induction coil is located between the PCB and the housing body. Therefore, when the induction coil needs to be maintained, it is merely necessary to disassemble the bottom cover, and the induction coil can be disassembled with the bottom cover, which can effectively improve the maintenance efficiency.

### BRIEF DESCRIPTION OF DRAWINGS

FIG. 1 is a structural view one of a wireless charger according to an embodiment of the present disclosure;

FIG. 2 is a structural view two of a wireless charger according to an embodiment of the present disclosure;

FIG. 3 is an exploded view one of a wireless charger according to an embodiment of the present disclosure; and

FIG. 4 is an exploded view two of a wireless charger according to an embodiment of the present disclosure.

In the Drawings:

1. Housing; 11. Housing body; 111. Middle frame; 1111. Second clamping protrusion; 1112. Installation groove; 1113. Installation hole; 1114. Positioning rib; 1115. Positioning groove; 112. Top cover; 113. Installation cavity; 12. Bottom cover; 121. First end surface; 122. Second end surface; 123. First clamping protrusion; 124. Countersunk hole; 2. PCB; 21. Positioning protrusion; 22. Connection groove; 3. Induction coil; 4. Connector; 41. Lug; 5. Connection component; 51. Bolt; 52. Nut; 6. Plug; 7. Protective film; 8. Hanging buckle.

### DETAILED DESCRIPTION

The technical solutions of the present disclosure will be described clearly and completely in combination with the drawings.

In the description of the present disclosure, it should be noted that the orientations or positional relationships indicated by the terms “center”, “up”, “down”, “left”, “right”, “vertical”, “horizontal”, “inside”, “outside” etc. are based on the orientations or positional relationships shown in the drawings, and are merely for the convenience of describing the present disclosure and simplifying the description rather than indicating or implying that the device or element referred to must have a specific orientation and structure and operation in a specific orientation, so cannot be understood as a limitation to the present disclosure. In addition, the terms “first”, “second” are used merely for descriptive purposes and should not be understood as indicating or implying relative importance. The terms “first position” and “second position” are two different positions, and when the first feature is described as “on”, “above” or “over” the second feature, the first feature is right on, above or over the second feature or the first feature is obliquely on, above or over the second feature, or the first feature is simply at a higher level than the second feature. When the first feature is described as “below”, “under” or “underneath” the second feature, the first feature is right below, under or underneath the second feature or the first feature is obliquely below, under or underneath the second feature, or the first feature is simply at a lower level than the second feature.

In the description of the present disclosure, it should also be noted that unless otherwise expressly specified and limited, the terms “install”, “connection” and “connect” should be understood in a broad sense, for example, as fixed connection, detachable connection, or integral connection; as mechanical connection or electrical connection; as direct connection or indirect connection through an intermediate medium, and as communication inside two elements. For those of ordinary skill in the art, the specific meanings of the above terms in the present disclosure may be understood in specific cases.

The embodiments of the present disclosure will be described in detail below, the examples of the embodiments are shown in the drawings, where the same or similar reference numerals represent the same or similar elements or the elements with same or similar functions. The embodiments described below with reference to the drawings are exemplary, are merely used for explaining the present disclosure, and should not be understood as a limitation to the present disclosure.

This embodiment provides a wireless charger, which may specifically be the wireless charger for charging a watch. Of course, in other embodiments, the wireless charger may also be the wireless charger used for charging smart wearable products such as a bracelet.

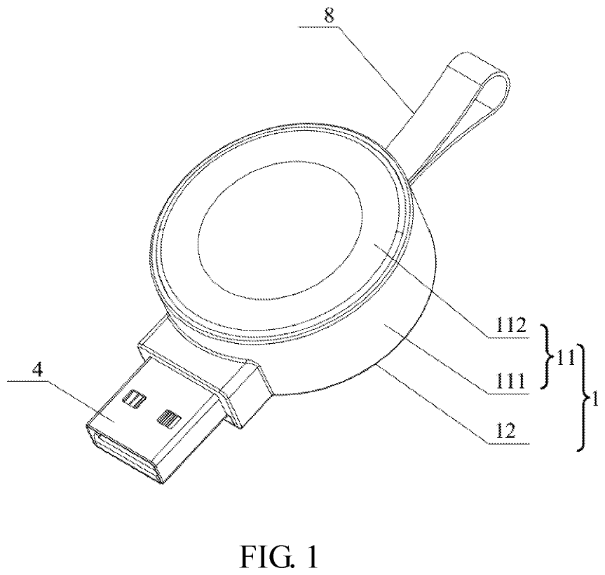

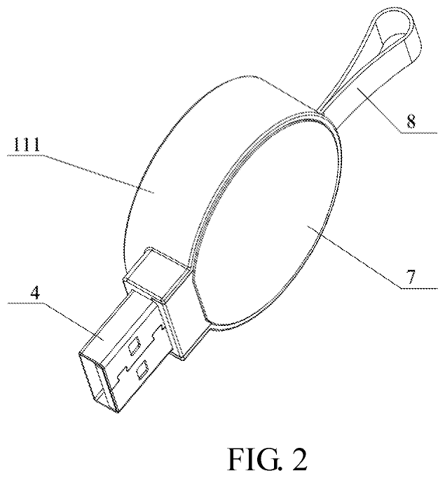

Specifically, as shown in FIGS. 1 to 4, the wireless charger includes a housing 1, a PCB 2, an induction coil 3, a connector 4 and a connection component 5. The housing 1 includes a housing body 11 and a bottom cover 12, an installation cavity 113 is provided in the housing body 11, an installation groove 1112 communicating with the installation cavity 113 is provided on the housing body 11, an opening is provided on a bottom side of the installation cavity 113, and the bottom cover 12 is provided on the opening and close the opening; the PCB 2 and the induction coil 3 are both disposed in the installation cavity 113, the induction coil 3 is connected to the PCB 2, and the induction coil 3 and the bottom cover 12 are located on opposite sides of the PCB 2 respectively; the connector 4 is disposed in the installation groove 1112 and connected to the PCB 2; the connection component 5 connects the bottom cover 12 and the PCB 2. For the wireless charger provided in this embodiment, the PCB 2 is fixed on the bottom cover 12 through the connection component 5, and the induction coil 3 is located between the PCB 2 and the housing body 11. Therefore, when the induction coil 3 needs to be maintained, it is merely necessary to remove the bottom cover 12, and the induction coil 3 can be disassembled with the bottom cover 12, which can effectively improve the maintenance efficiency.

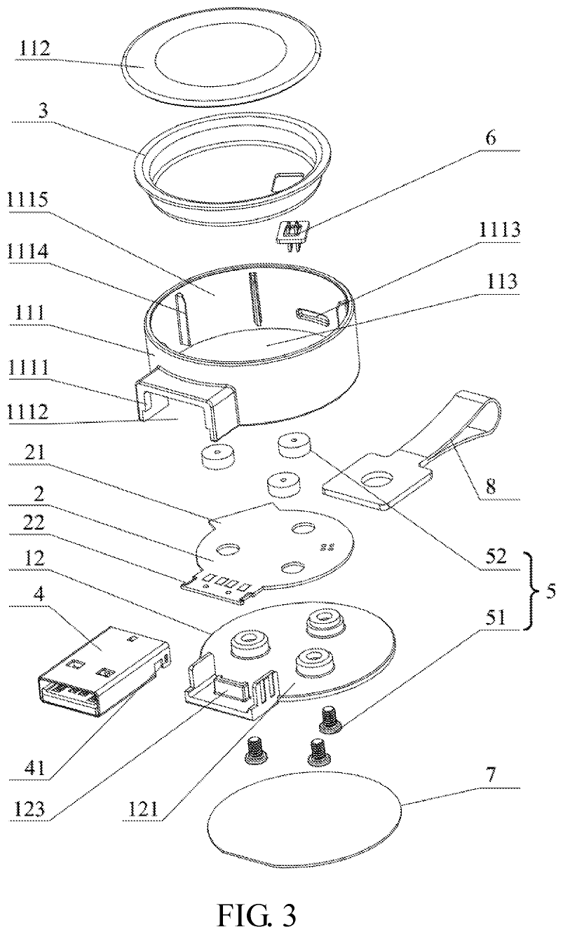

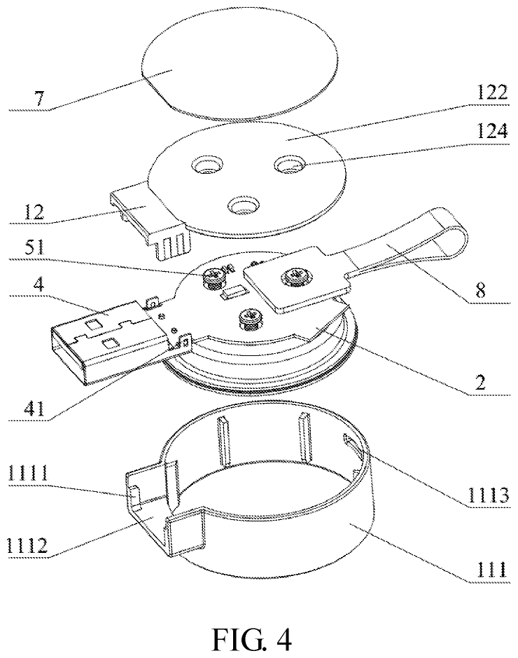

As shown in FIGS. 3 and 4, the connection component 5 includes a bolt 51 and a nut 52. The bolt 51 passes through the bottom cover 12 and the PCB 2 in sequence and is in threaded connection with the nut 52, and the induction coil 3 abuts the nut 52. The PCB 2 and the bottom cover 12 are connected by the bolt 51 and the nut 52 to ensure the installation stability of the PCB 2. The induction coil 3 is supported by the nut 52 without EVA cotton disposed, which can effectively reduce the cost compared with the related art. In this embodiment, the induction coil 3 is connected with a plug 6, and the plug 6 is plugged into the PCB 2. Alternatively, the wireless charger includes a plurality of connection components 5, and the PCB 2 and the bottom cover 12 are fixed through the plurality of connection components 5 to further ensure the installation stability of the PCB 2. In this embodiment, an exemplary solution is provided for fixing the PCB 2 and the bottom cover 12 through three connection components 5, and the three connection components 5 are distributed in a triangular shape. In other embodiments, the connection component 5 may also include the bolt 51 merely, and the bolt 51 passes through the bottom cover 12 to be in threaded connection with the PCB 2.

Optionally, the wireless charger further includes a hanging buckle 8, an installation hole 1113 is provided on a side wall of the housing body 11, the hanging buckle 8 passes through the installation hole 1113, and one bolt 51 passes through the bottom cover 12, the PCB 2 and the hanging buckle 8 in sequence to be in threaded connection with the corresponding nut 52. The hanging buckle 8 is provided, so that the wireless charger is convenient to carry, and the hanging buckle 8 is fixed to the PCB 2 through the nut 52 and bolt 51 to ensure the installation stability of the hanging buckle 8.

In this embodiment, the bottom cover 12 has a first end surface 121 and a second end surface 122 disposed oppositely, the first end surface 121 is located in the installation cavity 113, the second end surface 122 is located outside the installation cavity 113, and the second end surface 122 is provided with a countersunk hole 124; the bolt 51 passes through the countersunk hole 124 and a head of the bolt 51 does not exceed the second end surface 122, which can ensure that the second end surface 122 of the bottom cover 12 is flat. Alternatively, the wireless charger further includes a protective film 7, and the protective film 7 covers the second end surface 122 and shields the countersunk hole 124. The protective film 7 is provided to shield the countersunk hole 124, so that the wireless charger can be made more beautiful.

Optionally, two positioning ribs 1114 are spaced apart on a side wall of the installation cavity 113, a positioning groove 1115 is formed between the two positioning ribs 1114, a positioning protrusion 21 is provided on the PCB 2, and the positioning protrusion 21 is inserted into the positioning groove 1115. In this embodiment, the installation cavity 113 is a cylindrical cavity, and the two positioning ribs 1114 are spaced apart in a circumferential direction of the installation cavity 113. The PCB 2 is inserted into the positioning groove 1115, so that the PCB 2 can be prevented from being installed reversely, and the PCB 2 is further limited through the housing body 11.

Optionally, the housing body 11 includes a middle frame 111 and a top cover 112, the middle frame 111 and the top cover 112 surround and form the installation cavity 113, the induction coil 3 abuts the top cover 112, and the installation groove 1112 and the opening are disposed in the middle frame 111, which facilitates machining and assembly. The watch can be placed on the top cover 112 when the watch is being charged.

In this embodiment, the connector 4 is specifically a USB, two lugs 41 are spaced apart on the USB, two connection grooves 22 are spaced apart on the PCB 2, and the two lugs 41 are respectively inserted into the two connection grooves 22. The lug 41 can abut a groove wall of the connection groove 22 in the plugging direction of the USB. In this way, the connection strength between the USB and the PCB 2 can be ensured, and the solder joint welded between the USB and the PCB 2 can be prevented from falling off.

Optionally, a first clamping protrusion 123 is provided on the bottom cover 12, and the first clamping protrusion 123 abuts the PCB 2 in the plugging direction of the USB. The first clamping protrusion 123 abuts the PCB2, so that when the USB is unplugged, the bottom cover 12 can limit the PCB 2 and reduce the force between the PCB 2 and the bolt 51. Alternatively, the middle frame 111 is provided with a second clamping protrusion 1111, and the second clamping protrusion 1111 abuts the bottom cover 12 in the plugging direction of the USB. In this way, when the USB is plugged and unplugged, the force between the USB and the PCB 2 can be shared between the middle frame 111 and the bottom cover 12 to prevent the PCB 2 from being damaged.

1. A wireless charger, comprising:
a housing (1) comprising a housing body (11) and a bottom cover (12), wherein an installation cavity (113) is disposed inside the housing body (11), the housing body (11) is provided with an installation groove (1112) communicating with the installation cavity (113), a bottom side of the installation cavity (113) is provided with an opening, and the bottom cover (12) is disposed on the opening and closes the opening;
a printed circuit board (PCB) (2) disposed in the installation cavity (113);
an induction coil (3) disposed in the installation cavity (113) and connected to the PCB (2), wherein the induction coil (3) and the bottom cover (12) are located on opposite sides of the PCB (2) respectively;
a connector (4) disposed in the installation groove (1112) and connected to the PCB (2); and
a connection component (5) connecting the bottom cover (12) and the PCB (2).

2. The wireless charger according to claim 1, wherein
the connection component (5) comprises a bolt (51) and a nut (52), the bolt (51) passes through the bottom cover (12) and the PCB (2) in sequence and is in threaded connection with the nut (52), and the induction coil (3) abuts the nut (52).

3. The wireless charger according to claim 2, comprising a plurality of connection components (5), and further comprising a hanging buckle (8);
wherein an installation hole (1113) is disposed on a side wall of the housing body (11), the hanging buckle (8) passes through the installation hole (1113), and one bolt (51) passes through the bottom cover (12), the PCB (2), and the hanging buckle (8) in sequence to be in threaded connection with a corresponding nut (52).

4. The wireless charger according to claim 2, wherein
the bottom cover (12) has a first end surface (121) and a second end surface (122) disposed oppositely, the first end surface (121) is located in the installation cavity (113), the second end surface (122) is located outside the installation cavity (113), and a countersunk hole (124) is disposed on the second end surface (122); and
the bolt (51) passes through the countersunk hole (124) and a head of the bolt (51) does not exceed the second end surface (122).

5. The wireless charger according to claim 4, further comprising: a protective film (7) covering the second end surface (122) and shielding the countersunk hole (124).

6. The wireless charger according to claim 1, wherein
two positioning ribs (1114) are spaced apart on a side wall of the installation cavity (113), a positioning groove (1115) is formed between the two positioning ribs (1114), a positioning protrusion (21) is provided on the PCB (2), and the positioning protrusion (21) is inserted into the positioning groove (1115).

7. The wireless charger according to claim 1, wherein
the housing body (11) comprises a middle frame (111) and a top cover (112), the middle frame (111) and the top cover (112) surround and form the installation cavity (113), the induction coil (3) abuts the top cover (112), and the installation groove (1112) and the opening are both disposed in the middle frame (111).

8. The wireless charger according to claim 7, wherein
the connector (4) is a universal serial bus (USB), two lugs (41) are spaced apart on the USB, two connection grooves (22) are spaced apart on the PCB (2), and the two lugs (41) are inserted into the two connection grooves (22) respectively.

9. The wireless charger according to claim 8, wherein
a first clamping protrusion (123) is disposed on the bottom cover (12), and the first clamping protrusion (123) abuts the PCB (2) in a plugging direction of the USB.

10. The wireless charger according to claim 9, wherein
a second clamping protrusion (1111) is disposed on the middle frame (111), and the second clamping protrusion (1111) abuts the bottom cover (12) in the plugging direction of the USB.
